(19) United States
(12) Patent Application Publication
(10) Pub. No.: US 2023/0104601 A1
(43) Pub. Date: Apr. 6, 2023

(54) Evaporation boat and use of an evaporation boat

(71) Applicant: Kennametal Inc., Latrobe, PA (US)

(72) Inventor: Alexander Draken, Schongau (DE)

(21) Appl. No.: 17/948,484

(22) Filed: Sep. 20, 2022

(30) Foreign Application Priority Data
Sep. 30, 2021 (DE) 102021125370.5

(51) Int. Cl. C23C 14/24

(52) U.S. Cl. CPC C23C 14/243

(57) ABSTRACT

An evaporation boat comprising an evaporator body has an evaporator surface which extends along a longitudinal direction of the evaporator body from a first end face toward a second end face of the evaporator body. The evaporator body comprises at least one recess on an underside (20) opposite to the evaporator surface, so that the evaporator body has a thickness between the evaporator surface and the underside in the region of the at least one recess along its longitudinal direction which decreases from the center of the evaporator body in the longitudinal direction toward one of the end faces associated with the recess. The use of such an evaporation boat is specified as well.

### RELATED APPLICATION DATA

The present invention claims priority pursuant to 35 U.S.C. § 119(a) to German Patent Application Number 102021125370.5 filed Sep. 30, 2021 which is incorporated herein by reference in its entirety.

### FIELD

The invention relates to an evaporation boat and the use of an evaporation boat.

### BACKGROUND

So-called vacuum band metallization using PVD (physical vapor deposition) is a common method for coating flexible substrates with metals. The flexible substrate can be plastic film, metal foil, membranes or paper, for example. The most commonly used metal for coating substrates is aluminum. Substrates coated by means of PVD technology are widely used for packaging or decorative purposes. In addition to decorative purposes, the coating can in particular be used as surface protection or thermal insulation.

The evaporation of metals onto flexible substrates takes place in metallization systems. The substrate to be coated is passed over cooled rollers in the form of a long band, in the course of which the substrate is exposed to a metal vapor which is deposited on the substrate as a thin metal layer.

To generate the metal vapor, it is common to use evaporation boats. These are heated to temperatures of approximately 1700° C. using a direct passage of current. A metal wire, for example aluminum, is guided onto the preheated evaporation boat and first liquefies on an evaporator surface of the evaporation boat as a molten mass. It is then converted into the gas phase to form a metal vapor and coats the flexible substrate. The entire metallization process takes place in a vacuum, typically in a vacuum chamber at a low pressure of approximately 10⁻⁴ mbar, which ensures controlled evaporation of the metal.

At the locations where the evaporation boat is in direct contact with the molten metal, the evaporation boat is subject to heavy corrosion that limits the tool life or service life of the evaporation boat. In order to be able to reliably ensure a constant vapor flow, evaporation boats typically have to be replaced after about 15 operating hours.

The rate of corrosion is substantially dependent on the temperature to which the evaporation boat is heated, whereby a higher temperature results in a higher rate of corrosion. The temperature cannot arbitrarily be selected to be low, however, because otherwise uncontrolled flow of the metal liquefied on the surface of the evaporation boat can occur.

### SUMMARY

The object of the invention is to provide an evaporation boat that has a longer service life.

The object of the invention is achieved by an evaporation boat comprising an evaporator body, wherein the evaporator body comprises an evaporator surface which extends along a longitudinal direction of the evaporator body from a first end face toward a second end face of the evaporator body. The evaporator body comprises at least one recess on an underside opposite to the evaporator surface, so that the evaporator body has a thickness between the evaporator surface and the underside in the region of the at least one recess along its longitudinal direction which decreases from the center of the evaporator body in the longitudinal direction toward one of the end faces associated with the recess.

It has been found that, in known evaporation boats, the service life is limited, among other things, by the fact that an uneven temperature distribution occurs along the evaporator body, whereby an increased temperature and with it an increased rate of corrosion is observed in particular in the center of the evaporator body. This is a consequence of the brackets that are typically used near the end faces in metallization systems, which also provide cooling and thus cool the edge regions of the evaporation boat more.

A basic idea of the invention is to enable the most uniform possible temperature profile along the longitudinal direction of the evaporator body by varying the thickness of the evaporator body over its length, specifically such that it decreases from the center of the evaporator body toward the end faces. Therefore, when the evaporator body is heated, the electrical resistance increases from the center of said evaporator body toward the end face associated with the respective recess. This in turn increases the temperature of the evaporator body in the direction of the end face, so that an overall uniform temperature distribution or a uniform temperature profile is achieved, which results in the most uniform possible rate of corrosion over the length of the evaporator body.

The resulting temperature profile can be adjusted via the size and shape of the recess.

The thickness of the evaporator body in the region of the at least one recess preferably decreases substantially continuously along the longitudinal direction, i.e., decreases continuously, apart from unavoidable production-related deviations. A particularly uniform temperature profile of the evaporator body is thus achieved.

To increase the mechanical stability of the evaporation boat, the evaporator body can comprise an end region on the first end face and/or on the second end face and the at least one recess can extend from the center of the evaporator body to the end region of the associated end face, wherein the end region has a thickness which is equal to or greater than that of the center of the evaporator body.

The end regions can furthermore serve as clamping ends of the evaporation boat and/or can be provided with electrical contacts for direct heating of the evaporator body and can also be electrically contacted.

The end regions are in particular configured to be received in complementary brackets of a metallization system, wherein the brackets can be provided with cooling.

In one variant, the minimum of the thickness of the evaporator body along the longitudinal direction of the evaporator body is 75 % or less of the maximum of the thickness of the evaporator body, in particular 50 to 70 % of the maximum of the evaporator body. If the minimum of the thickness of the evaporator body is more than 75 % of the maximum of the thickness of the evaporator body, the mechanical stability of the evaporation boat and/or the service life can be compromised. If, on the other hand, the difference between the maximum and the minimum of the thickness is too small, the electrical resistance of the evaporator body may not differ enough over its length to achieve a satisfactorily uniform temperature distribution, so that the service life of the evaporation boat is at best increased insufficiently.

The thickness of the evaporator body is determined along a vertical direction perpendicular to the longitudinal direction.

The evaporator body preferably comprises a mirror plane which extends perpendicular to the longitudinal direction along a transverse direction through the center of the evaporator body.

In other words, the evaporation boat is preferably mirror-symmetrical. This results in a mirror-symmetrical temperature profile and thus the most uniform possible rate of corrosion along the longitudinal direction of the evaporator body.

In this variant, the evaporator body in particular comprises two recesses, wherein the first recess is associated with the first end face of the evaporator body and the second recess is associated with the second end face of the evaporator body.

The transverse direction extends perpendicular to both the longitudinal direction and the vertical direction of the evaporator body.

The evaporator body can furthermore have a trapezoidal cross-section along the transverse direction and the at least one recess can have a rectangular cross-section. This makes it possible to achieve a particularly good compromise between mechanical stability and the most uniform possible rate of corrosion along the longitudinal direction of the evaporator body. The known evaporation boats moreover often comprise an evaporator body with a trapezoidal cross-section, so that the evaporation boat according to the invention can be used in already existing metallization systems without the need for complex adjustments.

To keep the cost of manufacturing the evaporator body low, the recess can be created in the evaporator body by milling or grinding.

If the recess is created by grinding and the evaporator body comprises an end region on the end face associated with the recess, the result is in particular an arcuate transition of the recess into the end region.

The object of the invention is further achieved by the use of an evaporation boat as described above for evaporating metal in a PVD metallization system.

Using the evaporation boat according to the invention makes it possible to reduce the costs in the operation of the metallization system, because the evaporation boat has a long tool life or service life.

When evaporating metal, the evaporation boat is preferably heated to an operating temperature that exhibits a deviation of at most 10 % along the longitudinal direction of the evaporator body in the region of the at least one recess. This guarantees the most uniform possible rate of corrosion along the longitudinal direction of the evaporator body.

The operating temperature here refers in particular to the temperature of the evaporator body, specifically the evaporator surface of the evaporator body.

The operating temperature for evaporating metal is in particular 1500° C. or less. Due to the uniform temperature distribution of the evaporator body according to the invention, the operating temperature can be lowered overall without the operating temperature decreasing so much in the direction of the end faces of the evaporator body that unwanted flow of liquefied metal is to be expected. In other words, even higher temperatures near the center of the evaporator body can be avoided, which reduces the rate of corrosion and increases the service life of the evaporation boat.

However, the operating temperature has to still be high enough to reliably melt the metal and be able to ensure a desired evaporation rate of the metal from the evaporator surface as known in the prior art.

Further advantages and characteristics of the invention will emerge from the following description of an exemplary embodiment, which is not to be interpreted as limiting, and the drawings.

### BRIEF DESCRIPTION OF THE DRAWINGS

The figures show:

FIG. 1 a perspective view of an evaporation boat according to the invention from above at an angle,

FIG. 2 the evaporation boat of FIG. 1 in a perspective view from below at an angle,

FIG. 3 a bottom view of the evaporation boat of FIG. 1,

FIG. 4 a sectional view through the evaporation boat along the plane A-A of FIG. 1,

FIG. 5 a sectional view through the evaporation boat of FIG. 1 along a longitudinal direction,

FIG. 6 the sectional view of FIG. 5 during operation of the evaporation boat,

FIG. 7 a schematic illustration of temperature profiles of evaporation boats and

FIG. 8 a sectional view through an example of an evaporation boat as known in the prior art.

### DETAILED DESCRIPTION

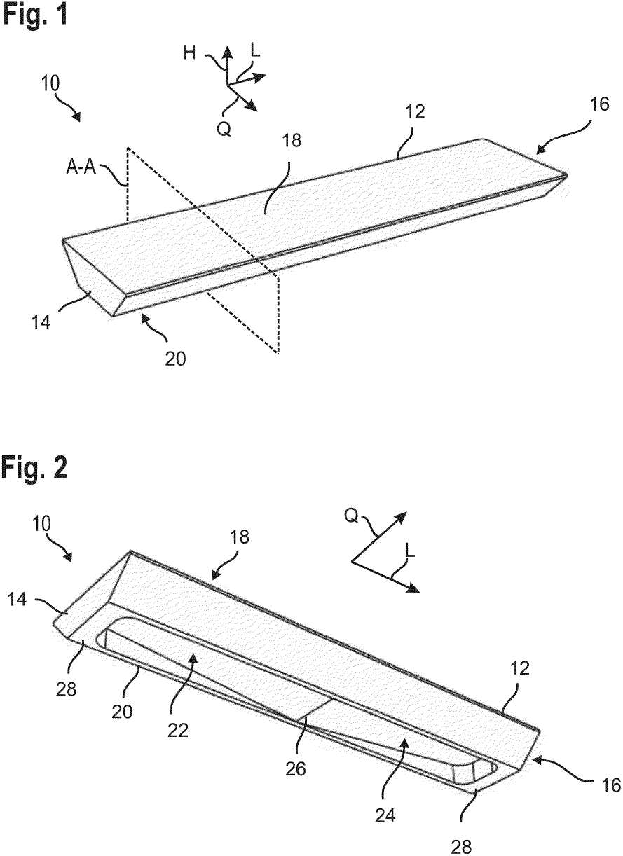

FIG. 1 shows an evaporation boat 10 according to the invention comprising an evaporator body 12.

The evaporator bodies 12 are made of a ceramic material, for example, the main constituents of which are titanium diboride (TiB₂) and boron nitride (BN), as well as optionally aluminum nitride (AIN). Titanium diboride acts as an electrically conductive component and boron nitride as an electrically insulating component, so that the electrical conductivity of the evaporator body 12 and thus of the evaporation boat 10 can be adjusted via the selected composition.

The evaporator body 12 extends along a longitudinal direction L from a first end face 14 toward an opposite second end face 16.

The evaporator body 12 further comprises an evaporator surface 18 and an underside 20 opposite to the evaporator surface 18.

FIG. 2 shows a perspective view of the evaporation boat 10 from below at an angle, in which it can be seen that the evaporator body 12 comprises two recesses 22 and 24 on its underside 20.

The recesses 22 and 24 extend from a center of the evaporator body 12, configured here as a central ridge 26, along the longitudinal direction toward one of the end faces 14 and 16, respectively, wherein the recess 22 is associated with the first end face 14 and the recess 24 is associated with the second end face 16.

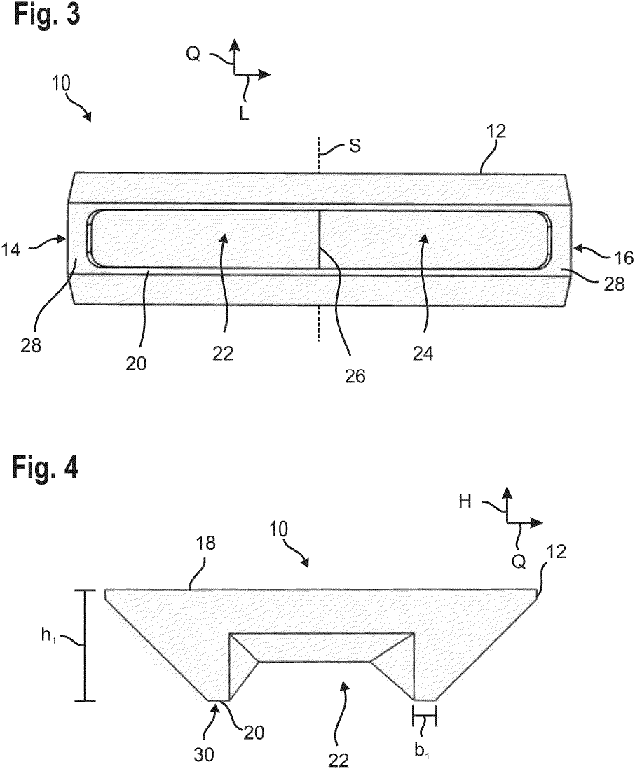

From FIG. 3, which is a bottom view of the evaporation boat 10, it can be seen that the evaporation boat 10 comprises a mirror plane S along the central ridge 26, which is perpendicular to the longitudinal direction L and parallel to the transverse direction Q.

In other words, the evaporation boat 10 in the shown embodiment is mirror-symmetrical.

The evaporator body 12 also comprises a respective end region 28 on both the first end face 14 and the second end face 16, wherein the recesses 22 and 24 extend only to the respective end region 28.

FIG. 4 shows a cross-section through the evaporator body 12 along the plane A-A of FIG. 1.

In this illustration, it becomes clear that the evaporator body 12 has a trapezoidal cross-section along the transverse direction Q, which is perpendicular to the longitudinal direction L and to a vertical direction H.

The recess 22, on the other hand, has a rectangular cross-section, which creates an edge portion 30 on the underside side 20 of the evaporator body 12 that contributes to the mechanical stability of the evaporator body 12.

The edge portion 30 has a width b₁ of up to 1 mm, for example, while the evaporator body 12 has a thickness h₁ of about 10 mm.

It goes without saying that the size and dimensions of the evaporation boat 10 can be adapted to the requirements of the metallization system in which the evaporation boat 10 is to be used.

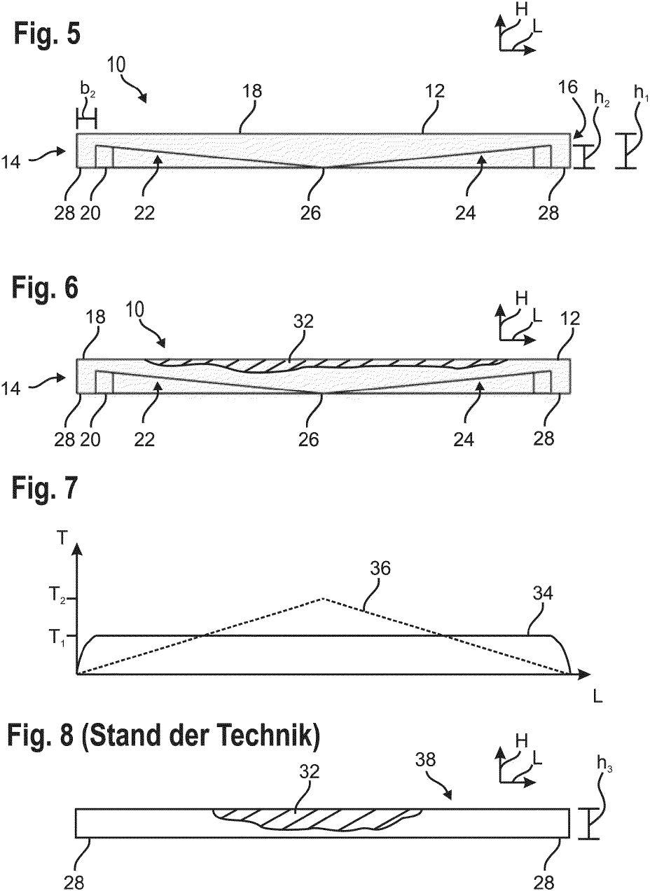

FIG. 5 shows a sectional view of the evaporation boat 10 along the longitudinal direction L.

From this illustration, it can be seen that, in the region of the respective recess 22 or 24, a thickness of the evaporator body 12 along the vertical direction H decreases continuously from the central ridge 26, i.e., from the center of the evaporator body 12, in the direction of the associated end face 14 or 16 to the respective end region 28.

The thickness of the evaporator body is thus reduced continuously, so that a minimum of the thickness of the evaporator body 12, which is shown in FIG. 5 as the thickness h₂, is reached at the transition of the recess into the respective end region 28.

In the shown embodiment, the thickness h₂ ranges from 5 to 7 mm, which results in a ratio h₂/h₁ of about 0.5 to 0.7. In other words, the minimum of the thickness of the evaporator body 12 along the longitudinal direction L is about 50 to 70 % of the maximum of the thickness of the evaporator body 12.

The end regions 28 have a width b₂ along the longitudinal direction L of about 3 to 10 mm.

The mode of operation of the evaporation boat 10 according to the invention is explained in the following.

The evaporation boat 10 is in particular used for evaporating metal in a (not depicted) PVD metallization system.

For this purpose, the evaporation boat 10 is inserted via the end regions 28 into a (not depicted) bracket, for example made of copper, which provides electrical contact to the evaporation boat 10, so that the evaporator body 12 can be heated to an operating temperature by direct current flow. The bracket further comprises cooling, for example water cooling.

A metal wire, for example made of aluminum, is then brought into contact with the evaporator surface 18 and is melted on the evaporator surface 18 because the evaporator body 12 is heated. The formed molten metal is subsequently evaporated, for example to coat a (not depicted) substrate being passed over the evaporator surface 18.

The molten metal results in corrosion of the evaporator surface 18, as indicated in FIG. 6 in the form of a corroded volume 32 shown with hatching, whereby the extent of corrosion, i.e., the rate of corrosion, increases as the operating temperature increases.

FIG. 7 schematically shows the progression of the temperature along the lengthwise direction L, i.e., the temperature profile of the evaporation boat 10, whereby the solid line 34 shows the temperature progression of the evaporation boat 10 according to the invention.

It can be seen that the temperature increases all the way across the end regions 28, i.e., all the way across their width b₂, to a plateau value T₁, which corresponds to the operating temperature.

The plateau value T₁ remains substantially unchanged over the region of the evaporator body 12 in which the recesses 22 and 24 extend. In this region, the operating temperature of the evaporator body 12 preferably deviates by no more than 10 %.

The plateau value T₁ is preferably 1500° C. or less.

This results in the most uniform possible corrosion along the lengthwise direction L of the evaporator body 12, so that the tool life or service life of the evaporation boat 10 increases.

The dashed line 36 in FIG. 7, on the other hand, schematically shows a temperature profile as would be expected for evaporation boats 38 known from the prior art (see FIG. 8), which have a constant thickness h₃ along their longitudinal direction L.

In this case, the cooling provided by the bracket disposed near the end regions 28 results in a temperature profile that increases toward the center of the evaporator body of the evaporation boat 38 to a peak temperature T₂ and then decreases again. In order to be able to ensure a sufficient operating temperature of the evaporation boat 38 over its entire length, the peak temperature T₂ is typically around 1700° C.

There are therefore significant differences in the rate of corrosion along the longitudinal direction L of the evaporation boat 38, whereby more severe corrosion is observed near the center of the evaporation boat 38 than in the end regions 28. This results in a shorter service life of the evaporation boat 38 than that of the evaporation boat 10 according to the invention.

1. An evaporation boat comprising an evaporator body,
wherein the evaporator body comprises an evaporator surface which extends along a longitudinal direction of the evaporator body from a first end face toward a second end face of the evaporator body and
wherein the evaporator body comprises at least one recess on an underside opposite to the evaporator surface, so that the evaporator body has a thickness between the evaporator surface and the underside in the region of the at least one recess along its longitudinal direction which decreases from the center of the evaporator body in the longitudinal direction toward one of the end faces associated with the recess.

2. The evaporation boat of claim 1, wherein the thickness of the evaporator body decreases substantially continuously in the region of the at least one recess along the longitudinal direction.

3. The evaporation boat of claim 1, wherein the evaporator body comprises an end region on the first end face and/or on the second end face and the at least one recess extends from the center of the evaporator body to the end region of the associated end face, wherein the end region has a thickness which is equal to or greater than that of the center of the evaporator body.

4. The evaporation boat of claim 1, wherein the minimum of the thickness of the evaporator body along the longitudinal direction of the evaporator body is 75 % or less of the maximum of the thickness of the evaporator body.

5. The evaporation boat of claim 1, wherein the evaporator body comprises a mirror plane which extends perpendicular to the longitudinal direction along a transverse direction through the center of the evaporator body.

6. The evaporation boat of claim 1, wherein the evaporator body has a trapezoidal cross-section along the transverse direction and the at least one recess has a rectangular cross-section.

7. The evaporation boat of claim 1, wherein the recess is created in the evaporator body by milling or grinding.

8. Use of an evaporation boat of claim 1 for evaporating metal in a PVD metallization system.

9. The use according to claim 8, wherein, when evaporating metal, the evaporation boat is heated to an operating temperature which exhibits a deviation of at most 10 % along the longitudinal direction of the evaporator body in the region of the at least one recess.

10. The use according to claim 9, wherein the operating temperature is 1500° C. or less.
